(19) United States
(12) Patent Application Publication
(10) Pub. No.: US 2015/0039955 A1
(43) Pub. Date: Feb. 5, 2015

(54) Systems and methods for Analog, Digital, Boundary Scan, and SPI Automatic Test Equipment

(71) Applicant: Mark Cheng Chien, Plano, TX (US)

(72) Inventor: Mark Cheng Chien, Plano, TX (US)

(21) Appl. No.: 14/284,077

(22) Filed: May 21, 2014

Related U.S. Application Data
(60) Provisional application No. 61/958,588, filed on Aug. 1, 2013.

(51) Int. Cl. G01R 31/3177

(52) U.S. Cl. CPC G01R 31/3177
USPC 714/727

(57) ABSTRACT

An Integrated Automatic Test Equipment that provides the test program development environments and execution of test programs for the assembled Print Circuit Boards. This test equipment includes Microsoft Windows PC executable programs, a digital/analog/SPI test controller, and a JTAG controller for boundary scan test. Both test controllers are attached to PC via USB ports for receiving test commands and replying test results. Test program development allows user to specify the rest stimulus and the expected test response for both digital test and boundary scan test. In addition to perform standalone tests, digital tester and boundary scan tester can drive and detect test signals to and from each other. The combination of digital test function and boundary scan test function can increase PCB production line test fault coverage.

### CROSS REFERENCE TO RELATED APPLICATIONS

This application contains the substitute specification of Ser. No. 14/284,077 filed May 21, 2014, which is to claim the benefit of U.S. Provisional Application No. 61/958,588, filed Aug. 1, 2013.

### BACKGROUND OF THE INVENTION

1. Field of the Invention

This invention generally relates to Automatic Test Equipments (ATE) systems and methods, particularly to the inter-working of digital tests and boundary scan tests to detect faults in assembled printed circuit boards.

2. Description of Related Art

Today's electronic manufacturers utilize In-circuit test (ICT) and boundary scan test (BST) ATE technologies to test the assembled printed circuit boards (PCB). ICT uses test probes to make contacts with tested PCB nodes for connecting to tester inputs and outputs pins. BST is used to test high pin-count, fine-pitch integrated circuit (IC) chips whose pins are not accessible from the test probes of ICT. Physically, BST uses the dedicated 4-pin test access port (TAP) built in each IC to control and observe the other IC pins during test operations.

BST and ICT technologies complement each other. Each technology covers one of the two disjoint PCB testing areas using its feature test access method that suits its own purpose. There is a gap between those 2 testing areas that needs to be handled in order to complete the test coverage. The test methods to close up that gap are done by validating the interactions between BST and various ICT technologies. Test stimulus originated from BST has to be received and verified by ICT, or vice versa. Long established ICT technologies include those of high speed digital (vector) testers and analog (vectorless) testers. There are advantages and limitations in their inter-working with BST.

Vector testers have very high test rate which is in sharp contrast to that of BST. Due to its operations on the serially connected boundary scan (BSC) cells of the tested IC pins, BST test rate is inversely proportional to the number of IC pins, and the number of IC chips that are concatenated serially in the tested PCB BSC device chain. The viability of BST inter-working with vector testers is hampered by the difficulty in their test interaction and synchronization. BST has to go through multiple TAP cycles in which each cycle performs BSC IC pins input and output operations with the interconnected circuitry. In comparison, vector testers complete its test sequence in one shot. Further compounding the inter-working difficulties, vector tester test stimulus and expected test results are generated using PCB logic circuit models and logic simulations without any consideration of interactions with BST.

Vectorless testers are characterized by the sequential test nature in that PCB testing is done one pin at a time. Overall test rate is substantially less than that of vector testing. In their test operations, vectorless testers utilize analog signal generators and detectors to send test stimulus and detect response to/from the PCB under test. Detection of PCB manufacturing faults, mainly the open pins, is done by comparing the PCB test responses with that of the known good tests. Synchronization with BST will not be an issue. For BST to do integrated test with the vectorless tester, it drives digital signals out-pulsing from BSC IC pins that serve as test stimulus to be picked up by external active capacitive probes mounted near the tested PCB and eventually detected and validated by the vectorless tester. This one-way test with test stimulus originated from BST and terminated at vectorless tester is used by current ATE industry leaders. Overall, this test binding is only limited by the nature of analog measurement in which marginal test response can lead to false test results. The vectorless test fixtures, which require exquisite intricacy, add up costs and can lead to reliability issues in the rigorous PCB production lines.

### SUMMARY OF THE INVENTION

This invention integrates BST with an interactive digital tester and combines their test operations directly, digitally, and symmetrically. In the test program development stage, digital tester and BST test stimulus and response can be specified using digital logic operators and logic assignment supported by a high level test programming language. There is no need to do the test simulation. During test execution, test controller facilitates direct 2-way digital signals exchanges between BST controllable BSC IC pins and digital tester pins. BST initiated digital signals driven by BSC IC pins can be detected by this digital tester directly and in parallel without using external active capacitive probes. On the other hand, this interactive digital tester can drive digital signals toward BSC IC pins and validated by BST. This capacity and functionality can increase the test performance and enhance the overall PCB test quality.

### BRIEF DESCRIPTION

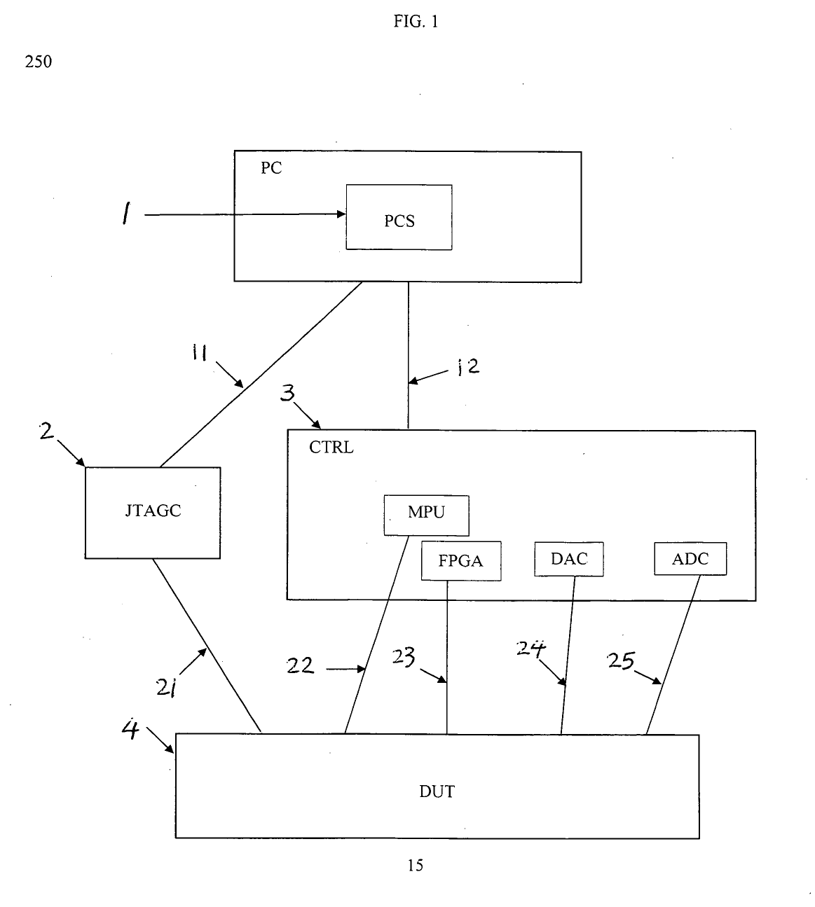

This general purpose test equipment is a Microsoft Windows Personal Computer (PC) based, Universal Serial Bus (USB, FIG. 1-11 and FIG. 1-12) interconnected systems that execute user programmable test instructions to perform test functions on the Device under Test (DUT, FIG. 1-4). Test functions include Digital test function (DTST) utilizing DTST pins indicated in FIG. 1-23, Analog test function (ATST) utilizing analog output pins indicated in FIG. 1-24 and analog input pins indicated in FIG. 1-25, Boundary scan (BSC) test function (BST) via JTAG (Joint Test Action Group) port indicated in FIG. 1-21, and Serial Peripheral Interface (SPI) devices test function (SPIT) via SPI port indicated in FIG. 1-22. This test system includes PC executable software modules (PCS, FIG. 1-1), a USB capable microprocessor (MPU) based DTST/ATST/SPIT Controller (CTRL, FIG. 1-3), and a JTAG Controller (JTAGC, FIG. 1-2). PCS creates the DUT test database and the test instructions, formulates test instructions into digital bit streams, and sends test instructions across the USB links to either CTRL or JTAGC during test execution. Test response digital bit streams will be returned to PCS. With test response analyzed, PCS will determine the test result, record the detailed test information, and display the test result to the user accordingly.

The ubiquity of USB devices and the advent of System on a Chip (SOC) are the driving force behind this invention. They provide an economical and efficient means to design this automatic test and measurement equipment. SOC, which integrates microprocessor with other electronic circuits into a single chip, provides an easier way to build a standalone system such as CTRL. Its build-in USB functionality facilitates the connectivity to the PC. Externally incorporated with Field Programmable Gate Arrays (FPGA), the test equipments which were usually built with racks of electronic circuit boards can be consolidated into a single board computer.

PCS provides the general purpose computer services to configure CTRL and JTAGC, creating users programmable test file systems, and controlling the execution of those test file systems during DUT testing. In addition to providing visual test results, PCS also records test stimulus and response into user readable text files for each DTST, ATST, BST, or SPIT test execution. In case that BST is included in the test execution, each of the devices within the BSC IC device chain will have an associated data logging file recording its BSC IC pins input, output, or control cells digital signal levels.

PCS allows users to define signal name (SIGNAM) for each ATST and DTST tester pin. Using SIGNAM, users can create more user-friendly test and measurement source programs. To further simplify test programming involving multiple SIGNAM, group name (GRPNAM) defines are provided for that purpose. In BST test programming, similar grouping of BSC port names of the BSC IC pins are also provided. In case of ATST, there is special provision for voltage level transformation between DUT pin and CTRL analog tester input/output pins (FIG. 1-25 and FIG. 1-24). With that, analog testing and measurement is possible for DUT pins whose voltage levels would otherwise be out of the driving/measurable range of the ATST pins.

PCS user creates test programs, which are made of strings of test instructions, by incrementally specifying the SIGNAM or GRPNAM to the designated level as CTRL/JTAGC might be interacting with DUT. In case of BST, the BSC port names and BSC port group names will be used in place of SIGNAM and GRPNAM. Test programming performing DTST, ATST, BST, or SPIT can arrange the test instructions at any order as needed. A PCS utility program will be provided to translate user's test program source file into binary test file (BIN). This process, in addition to validating user's test programs, also creates test data sets for PCS test execution.

PCS executes BIN with a fixed set of internal operations, regardless of the types of test instructions. It fetches a test instruction from BIN, composes one or more data streams and sends to either CTRL or JTAGC over the USB links. After receiving the test response, PCS is to validate the test response and log the test results. Test execution will be terminated when the end of BIN file is reached, or the END instruction is encountered.

To help PCS users to develop or debug test programs, a PCS utility is provided to simulate the test execution without interacting with DUT. PCS execution simulation will generate the logging files similar to those during normal test execution. The difference between PCS execution simulation logging files and those of normal test execution depends on the type of tests. For DTST and BST, expected test response logic levels will be put in places of those measured logic levels of the normal tests. ATST execution simulation logging file's analog output pins will display the range of output voltage levels driving DUT input pins accounting the voltage level transformation circuit between ATST output pins and DUT. Similarly, ATST execution simulation logging file's ATST input pins will display range of measurable DUT output pins voltage levels.

### DETAILED DESCRIPTION

1. This system executing DTST involves PCS, MPU, FPGA, and DTST pins (FIG. 1-23). PCS will send a DTST test instructions across USB link (FIG. 1-12) to be executed by CTRL. Within CTRL, MPU will execute the DTST test instruction and interact with DUT via the attached FPGA to drive DTST output pins as specified. At the end of DTST test, MPU will send the DTST test results back to PCS for test analysis.

2. This system executing ATST will use PCS, MPU, digital to analog converter (DAC) to drive analog output pins (FIG. 1-24), and analog to digital converter (ADC) to measure analog input pins (FIG. 1-25). DAC will perform the analog output functions while ADC will perform the analog input functions, under the control of MPU, which in turn following the ATST test or measurement instruction sent from PCS. At the end of the ATST measurement function, MPU will send the measured analog input pin data back to PCS for analysis.

3. This system executing SPIT will use PCS, MPU, and the SPI controller embedded within MPU. After receiving SPIT test instruction from PCS, MPU will send out SPI data streams to the DUT SPI device through the SPI port (FIG. 1-22). The data stream received from DUT SPI device, captured by the MPU, will be relayed back to PCS for test analysis.

4. This system executing BST involves PCS and JTAGC. For each BST test instruction, PCS will send a sequence of commands to JTAGC via USB link (FIG. 1-11). These commands include those for JTAGC internal control operations, and an output data stream to be sent over JTAG port (FIG. 1-21) to DUT's BSC IC device chain. That output data stream will be latched into BSC IC pins output and control cells which setup IC pins to drive to the digital logic levels specified in the BST test instruction. Simultaneously, JTAGC will receive an input data stream that contains the BSC IC pins input digital logic levels which are latched into their input cells. These IC pins input cells digital logic levels will be relayed back to PCS for test analysis.

5. The messages sent over the USB link (FIG. 1-12) between PC and CTRL are made of fixed length header indicating the type of test instruction or test response. Message headers will be followed by variable length data fields which vary with the message types.

6. This system facilitates the interactions of DTST with BST so that DUT BSC pins can be cross checked with DTST pins. In that, BSC IC pins output cells driving toward the digital logic levels setup by BST can be validated by the DTST operations. Conversely, DTST pins output operations can digitally drive toward BSC IC pins to be latched into its input cells and be validated by the BST operations.

7. This system facilitates the interactions of ATST with SPIT so that DUT SPI based analog devices can perform cross testing with ATST output pins (FIG. 1-24) and ATST input pins (FIG. 1-25). In case of a DUT SPI based analog to digital converter, an analog signal driven by ATST output pin can be validated by the SPIT digital data read back. For a DUT SPI based digital to analog converter, SPIT digital data sent to it which generates an analog voltage can be validated by an ATST input voltage measurement function.

8. ATST can drive or measure variable range of DUT voltage level using software voltage level transformation function and voltage level translator circuit inserted between CTRL and DUT.

9. PCS can send control message across USB link (FIG. 1-12) to control DUT pins attachment or detachment to the CTRL.

10. PCS can send control messages across USB link (FIG. 1-12) to turn on or turn off power supply to the DUT.

11. PCS can send control messages across USB link (FIG. 1-12) to change DTST and ATST test response waiting time.

What is claimed:

1. Automatic test equipment systems and methods that utilize digital tester to drive or detect DUT's BSC IC pins digital logic levels which can be detected or driven digitally by an inter-working BST which is running concurrently within the same automatic test equipment. In case that digital tester is driving, it will drive DTST pins to the test program specified digital logic levels which are directed to drive DUT's BSC IC pins. Following that, a BST test operation can be executed to capture those BSC IC pins input digital logic levels and concludes the BST test results by comparing the captured BSC IC pins input cells digital logic levels with those expected in BST test instruction. On the opposite test driving direction, BST test operation will guide DUT's BSC IC pins to drive the BST test instruction specified digital logic levels which will be directed to drive DTST pins. The digital tester operation that follows will capture DTST input pins and conclude the DTST test results by comparing returned DTST input pins digital logic levels with those expected in DTST test instruction. These inter-workings between DTST and BST can help better identifying DUT's BSC IC pins faults such as open pin or short circuit with other DUT pins.

2. In the digital tester driving test operations of claim 1, driving DTST pins digital logic levels are specified via a test instruction issued from PCS to CTRL over the USB link (FIG. 1-12). The MPU within CTRL will decode the test instruction and setup FPGA to drive the DTST pins to the specified digital logic levels. These DTST pins will be detected by DUT's BSC IC pins input cells and be captured and verified by the follow on BST test operation. In the BST test operation, PCS will issue a series of TAP commands to JTAGC sent over the USB link (FIG. 1-11). Following those TAP commands, JTAGC will send DUT's BSC IC pins input cells digital logic levels back to PCS. This BST data stream received by PCS reflects the previous DTST test operation. From that, PCS can draw the BST test results by comparing the received BSC IC pins input cells digital logic levels with those expected in the BST test instruction.

3. In the BST driving test operations of claim 1, PCS will issue a string of TAP commands to JTAGC over the USB link (FIG. 1-11). Following those commands, JTAGC will setup DUT's BSC IC pins output and control cells to drive the digital logic levels specified by the BST test instruction. Those BSC IC pins will be directed to drive DTST pins and be verified by the follow on DTST operation. In the DTST test operation, PCS will issue a test instruction to CTRL over the USB link (FIG. 1-12). The MPU within CTRL will decode the test instruction and setup FPGA to input the DTST pins which include those detecting DUT's BSC IC pins driving digital logic levels. MPU will eventually reply to the PCS test instruction with the DTST input pins logic levels. From that, PCS can draw the DTST test results by comparing the detected DTST input pins digital logic levels with test program specified expected DTST input pins digital logic levels.
